(19) United States
(12) Patent Application Publication
(10) Pub. No.: US 2009/0115017 A1
(43) Pub. Date: May 7, 2009

(54) SELECTIVE FORMATION OF TRENCHES IN WAFERS

(75) Inventor: Steve Chang, Redmond, WA (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International Inc., Morristown, NJ (US)

(21) Appl. No.: 11/933,978

(22) Filed: Nov. 1, 2007

(51) Int. Cl. H01L 29/00; H01L 21/762

(52) U.S. Cl. 257/510; 438/425; 257/E29.001; 257/E21.546

(57) ABSTRACT

A wafer substrate, such as a silicon wafer substrate, includes at least one selectively formed substrate trench that may be filled with an isolation material to form an isolation surface. The forming process includes converting at least one silicon wall etched into the wafer substrate into a silicon dioxide wall, which in turn creates a substantially larger substrate trench in the wafer substrate. The selectively formed and substantially larger substrate trench may be filled with an isolation material, such as silicon dioxide, through at least one or both of an oxidation growth process and an oxidation deposition process.

### BACKGROUND OF THE INVENTION

The growth of silicon dioxide (SiO₂) by the thermal oxidation of silicon (Si) is the fundamental film growth process used in the fabrication of silicon wafers to make integrated circuits. The SiO₂ is generally used for passivating the Si surface, for masking diffusion, for creating ion implantation layers, for growing dielectric films, and for providing an interface between the Si surface and other materials. In micromachined or Microelectromechanical systems (MEMS), SiO₂ may be used as etch masks and sacrificial layers, which will be discussed later. Although Si exposed to air at room temperature will grow a native oxide (about 20 Å thick), thicker oxide films (0.5-1.5 μm) can be grown at elevated temperatures. For a fixed temperature, oxide thickness increases with time in parabolic fashion. Initially, the growth of silicon dioxide is a surface reaction. However, after the SiO₂ thickness begins to build up, the arriving oxygen molecules must diffuse through the growing SiO₂ layer to get to the silicon surface in order to react.

A popular model for the oxide growth kinetics is the “Deal/Grove” model. This model is generally valid for temperatures between 700 and 1300 C, partial pressures between 0.2 and 1.0 atmospheres, and oxide thicknesses between 0.03 and 2 microns for both wet and dry oxidation.

As noted above, the SiO₂ layer is generally grown and then deposited on desired or isolated areas of a silicon wafer. The growing of the SiO₂ layer consumes portions of the silicon (Si) and produces a base onto which additional SiO₂ may be deposited. However, one drawback of forming the SiO₂ on the isolated areas of the silicon wafer is that the growth or deposition process takes a long time and may generate high stresses, especially if the SiO₂ layer exceeds 3-4 microns (μm) in thickness. Another drawback with forming substantially thick SiO₂ layer on a silicon wafer is the generation of internal SiO₂ residual stresses, which may be caused from temperature gradients across the material or caused by the orientation of the wafer during the SiO₂ growth process. Yet another drawback with forming substantially thick SiO₂ layer on a silicon wafer is a problem commonly referred to as “birds beak,” such as when the SiO₂ layer bulges out under a masked (e.g., nitride) layer.

In view of the drawbacks discussed above, selectively forming substantially large trenches in a silicon wafer and then filling the trenches with an isolation material has proven to be difficult, time consuming, and practically impossible in the industry. It is estimated that the amount of time to grow or deposit silicon dioxide into a single etched trench of 50 or more microns in width, and where the trench does not include any intermediate silicon walls, would be close to one year.

### BRIEF SUMMARY OF THE INVENTION

The present invention, according to at least one embodiment, generally relates to a wafer substrate, such as a silicon wafer substrate, having at least one selectively formed substrate trench that may be filled with an isolation material to form an isolation surface. The forming process includes converting at least one silicon wall separating etched trenches into a silicon dioxide wall, which in turn provides a substantially larger substrate trench in the wafer substrate. Further, the forming process may include the growth and/or deposition of silicon dioxide within the substrate trench.

In one aspect of the invention, a method for producing an isolation region on a silicon wafer includes arranging a desired pattern onto a surface of the silicon wafer; etching a plurality of trenches into the silicon wafer, each trench having a depth that extends through at least a partial thickness of the silicon wafer, the plurality of trenches corresponding to the desired pattern and wherein a silicon wall separates adjacently etched trenches; and oxidizing at least the etched portion of the silicon wafer such that the silicon wall is substantially converted to a silicon dioxide wall and a substantially large trench is formed in the silicon wafer, the substantially large trench including at least a total volume of the plurality of trenches formed during etching, and the substantially large trench providing a surface to operate as the isolation region on the silicon wafer.

In another aspect of the invention, a silicon wafer includes a silicon substrate having a support surface located adjacent to a substrate trench formed in the silicon substrate, the substrate trench formed through an oxidation process wherein at least one silicon wall separating two previously etched trenches is converted to a silicon dioxide wall; and an isolation material including at least the silicon dioxide wall received in the substrate trench and substantially filling the substrate trench, wherein an isolation surface formed by the isolation material is substantially flush and located adjacent to the support surface of the silicon substrate.

### BRIEF DESCRIPTION OF THE DRAWINGS

Preferred and alternative embodiments of the present invention are described in detail below with reference to the following drawings:

FIG. 1A is a top plan view of a wafer assembly with masking material placed thereon according to an illustrated embodiment of the invention;

FIG. 1B is a cross-sectional view, taken along line 1B-1B of FIG. 1A, of the wafer assembly with the masking material forming a first pattern;

FIG. 1C is a cross-sectional view, taken along line 1C-1C of FIG. 1A, of the wafer assembly with the masking material forming a second pattern;

FIG. 1D is a cross-sectional view, taken along line 1D-1D of FIG. 1A, of the wafer assembly with the masking material forming a third pattern;

FIG. 2A is a top plan view of a wafer assembly after a number of patterns have been etched into a substrate of the assembly according to an illustrated embodiment of the invention;

FIG. 2B is a cross-sectional view, taken along line 2B-2B of FIG. 2A, of the wafer assembly with a first pattern etched into the substrate;

FIG. 2C is a cross-sectional view, taken along line 2C-2C of FIG. 2A, of the wafer assembly with a second pattern etched into the substrate;

FIG. 2D is a cross-sectional view, taken along line 2D-2D of FIG. 2A, of the wafer assembly with a third pattern etched into the substrate;

FIG. 3A is a top plan view of a wafer assembly after a dielectric or isolation layer material has been grown on the etched substrate surface through an oxidation process according to an illustrated embodiment of the invention;

FIGS. 3B-3D are cross-sectional views, taken along line 3B-3B, 3C-3C, and 3D-3D, respectively, of FIG. 3A, showing substantially large trenches formed in a substrate;

FIG. 4A is a top plan view of a wafer assembly after a deposited layer material has been deposited on the dielectric or isolation layer through an oxidation deposition process according to an illustrated embodiment of the invention;

FIGS. 4B-4D are cross-sectional views, taken along line 4B-4B, 4C-4C, and 4D-4D, respectively, of FIG. 4A, showing substantially large trenches filled with dielectric and deposited materials;

FIG. 5A is a top plan view of a wafer assembly after a finishing process to create an isolation pad according to an illustrated embodiment of the invention;

FIGS. 5B-5D are cross-sectional views, taken along line 5B-5B, 5C-5C, and 5D-5D, respectively, of FIG. 5A, showing the wafer assembly with various configurations of isolation pads.

### DETAILED DESCRIPTION OF THE PREFERRED EMBODIMENT

In the following description, certain specific details are set forth in order to provide a thorough understanding of various embodiments of the invention. However, one skilled in the art will understand that the invention may be practiced without these details or with various combinations of these details. In other instances, well-known structures and methods associated with silicon wafers, chips, and sensors, to include the manufacturing thereof may not be shown or described in detail to avoid unnecessarily obscuring descriptions of the embodiments of the invention.

The following description is generally directed to a wafer substrate, such as a silicon wafer substrate, having at least one selectively formed substrate trench that may be filled with an isolation material to form an isolation surface. The forming process includes converting at least one silicon wall etched into the wafer substrate into a silicon dioxide wall, which in turn creates a substantially larger substrate trench in the wafer substrate. The selectively formed and substantially larger substrate trench may be filled with an isolation material, such as silicon dioxide, through at least one or both of an oxidation growth process and an oxidation deposition process.

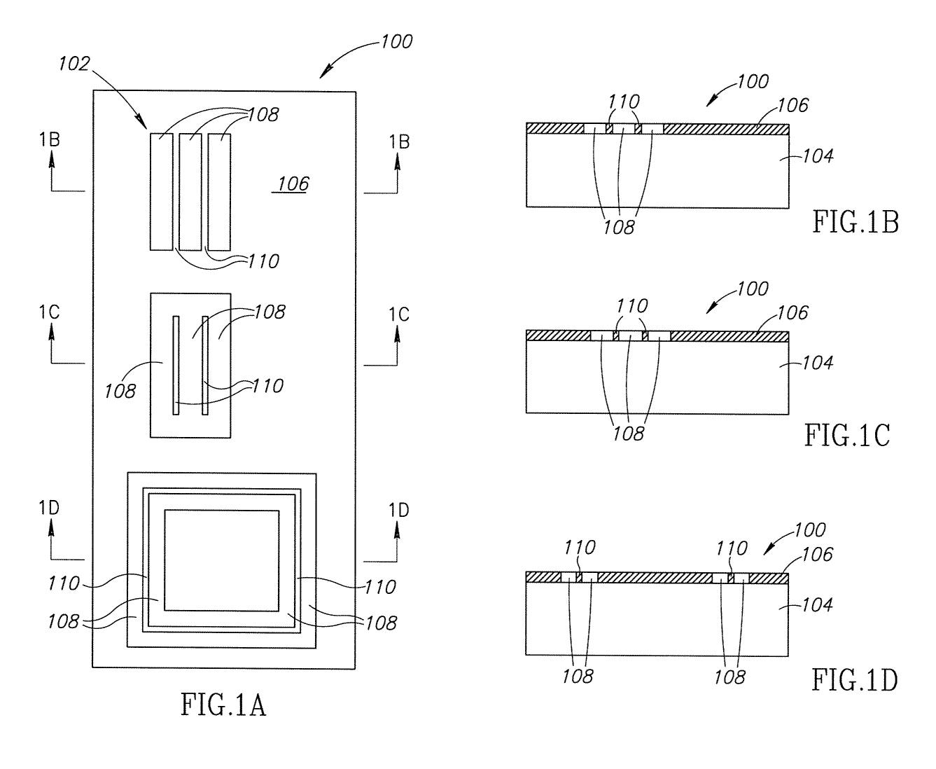

FIGS. 1A-1D shows a first processing step for producing a wafer assembly 100. FIG. 1A provides a top plan view of the wafer assembly 100 with a number of different etching patterns 102 that may be etched into a substrate material 104. The various patterns 102 are merely representative of various etching patterns and are thus not limited to the illustrated patterns. By way of example, FIG. 1B shows a cross-sectional view of the wafer assembly 100 with a first pattern formed by a masking material 106. FIG. 1C shows a cross-sectional view of the wafer assembly 100 with a second pattern formed in the same masking material 106. And, FIG. 1D shows a cross-sectional view of the wafer assembly 100 with a third pattern formed in the same masking material 106. The masking material 106 includes openings 108 separated by intermediate walls 110. For purposes of brevity and clarity, the following description will be directed to the first pattern (e.g., FIGS. 1B, 2B, 3B, 4B, and 5B).

Still referring to FIG. 1B, the masking material 106 may be any type of material or substance typically used in a dry or wet etching process. In one embodiment, the masking material 106 may be a layer made from photo resist, oxide, silicon nitride, metal, or some combination thereof. For example, a photo resist mask may be spin coated on a silicon surface. The thickness of the mask material 106 may determine the depth or width of trench is placed on a silicon substrate 104 so the various patterns, as shown in FIGS. 1B, 1C and 1D, may be etched, (e.g., deep reactive ion etched (DRIE)) into the silicon substrate 104. Preferably, the openings 108 and walls 110 forming the pattern are formed with respective widths (e.g., sufficiently narrow) that permit a reduced oxidation time for the oxide growth and/or deposition processes described below.

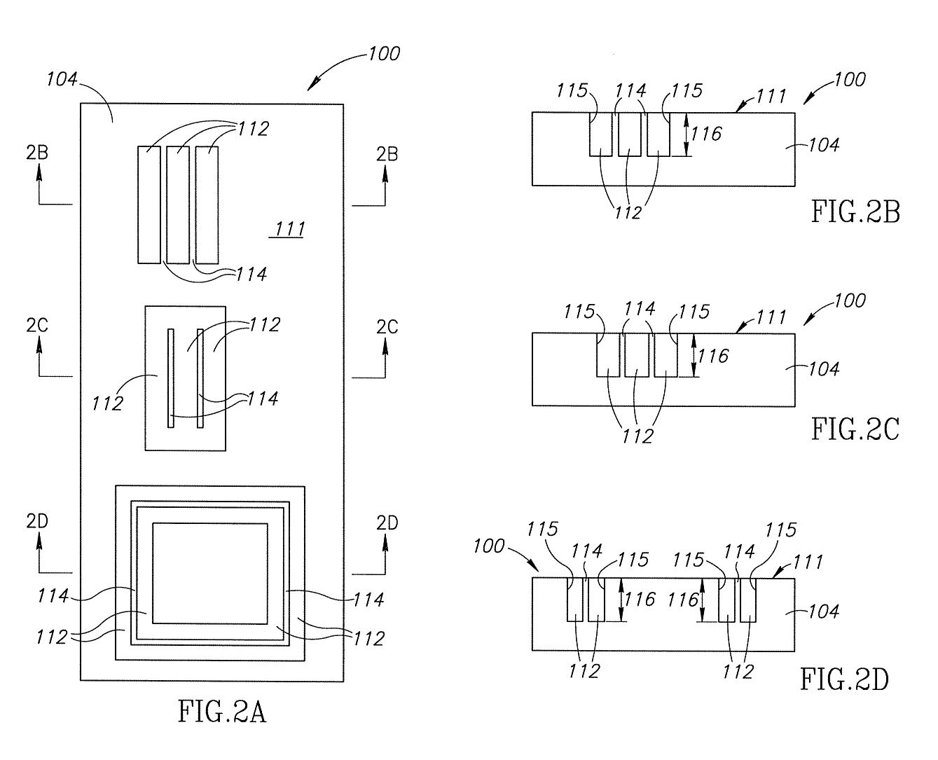

FIGS. 2A-2D show the wafer assembly 100 and in particular show the substrate wafer 104 after the substrate trenches 112 have been etched into the substrate wafer 104 and after the masking material 106 (FIGS. 1A-1D) has been removed to expose a substrate wafer surface 111. The configuration of the substrate trenches 112 corresponds to the openings 108 (FIGS. 1B-D) of the masking material 106. The depth, width, and thickness of the walls 110 may be determined by the design of wager assemblies 100. In one embodiment, the depth may be in a range of about 10 μm-100 μm and the width may be larger than 10 μm. By way of example, the width of the walls 100 and the tracks 112 may be in a range of about 0.10 μm to 15 μm. In one embodiment, the substrate trenches 112 are defined by a substrate trench wall 114 and a substrate trench sidewall 115. In the illustrated embodiment, the substrate trenches 112 have an etched depth 116. Further and in another embodiment, the substrate wafer 104 is made of silicon and correspondingly the substrate trench wall 114 and substrate sidewalls 115 are silicon. As noted above, the arrangement of the resulting substrate trenches 112 and substrate trench walls 114 are determined by the patterns selected when the masking material 106 (FIGS. 1A-1D) is placed on the substrate wafer 104. In an optional embodiment, the masking material 106 may be left on the substrate wafer surface 111.

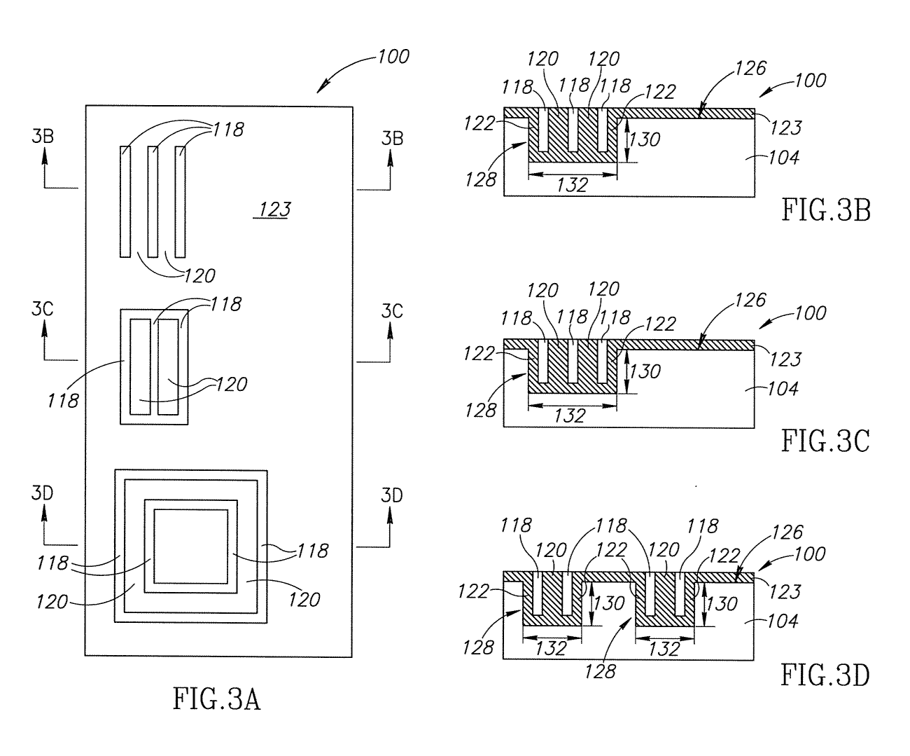

FIGS. 3A-3D show the wafer assembly 100 either during or after an oxidation growth process. FIG. 3A shows trenches 118, oxidized intermediate walls 120, and oxidized sidewalls 122 that may be formed during the oxidation growth process. The methods and processes used to oxidize a silicon wafer substrate 104, such as growing a dielectric film or layer 123 on the substrate 104, are generally well known and will not be described in detail. For purposes of the description herein, the dielectric layer 123 may also be referred to as an isolation layer.

FIGS. 3B-3D show the layer 123 of silicon dioxide complementarily formed on an etched surface 126 of the silicon substrate 104 as a result of the oxidation growth process. The oxidized intermediate walls 120 and sidewalls 122 are comprised substantially of silicon dioxide, which in turn is created when the silicon trench wall 114 and silicon sidewalls 115 (FIGS. 2B-2D) are converted into silicon dioxide through the oxidation growth process, thus creating the trenches 118, oxidized intermediate walls 120, and oxidized sidewalls 122. Alternatively stated, the silicon trench wall 114 and silicon sidewalls 115 are consumed during the oxidation growth process to form the trenches 118, oxidized intermediate walls 120, and oxidized sidewalls 122, each comprised of silicon dioxide.

As a result of the conversion and/or consumption process, a substantially larger trench 128, in comparison to the etched substrate trenches 112 (FIGS. 2B-2D) and further in comparison to the trenches 118, is formed in the silicon substrate 104. The larger trench 128 may be generally defined by a depth 130 and an overall width 132. By way of example in comparing FIG. 3B to FIG. 2B, the overall width 132 of the trench 128 may increase as the silicon sidewalls 115 are converted and/or consumed to form a portion of the dielectric layer 123. Optionally and during or after the dielectric layer 123 is produced, the wafer assembly 100 may be etched, such as buffered oxide etched (BOE) or hydrofluidic acid (HF) etched and then re-oxidized to complete the conversion and/or consumption process.

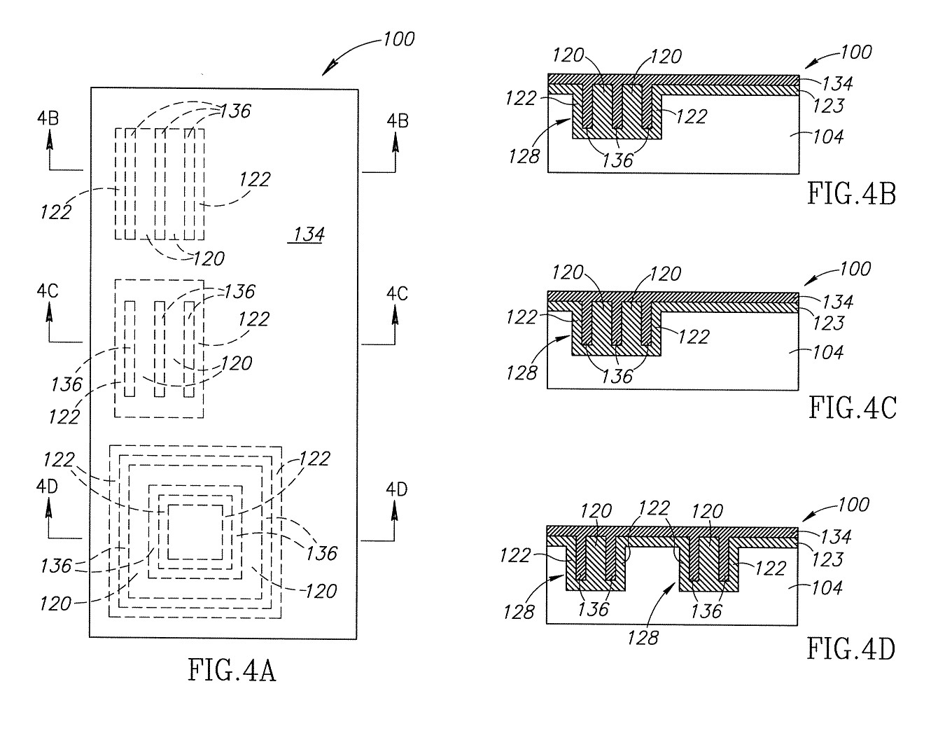

FIGS. 4A-4D show the wafer assembly 100 after the above-described oxidation deposition process in which a deposited layer 134 is arranged on the dielectric layer 123. One purpose of creating the deposited layer 134 is to fill in the trenches 118 described above with reference to FIGS. 3A-3D. FIG. 4A shows, in hidden line format, the oxidized intermediate walls 120, oxidized sidewalls 122, and deposit filled trenches 136. In one embodiment, the deposited layer 134 is a silicon dioxide material deposited onto the dielectric layer 123 using known deposition techniques. In another embodiment, the deposited layer 134 is a metallic, ceramic, or some other material that may be deposited, coated or otherwise formed on the dielectric layer 123. In one embodiment, the material that forms the deposited layer 134, which includes the filled trenches 136, is also a dielectric or isolation material.

The deposited layer 134 may be deposited such that it substantially conforms to the dielectric layer 123 and thus substantially fills the trenches 118 (FIGS. 3A-3D). But, if the deposited layer 134 is not conformal, the wafer assembly 100 may be annealed to remove any gaps, holes, or spaces along the interface of the dielectric layer 123 and the deposited layer 134. Conformal deposition is preferable, but not mandatory.

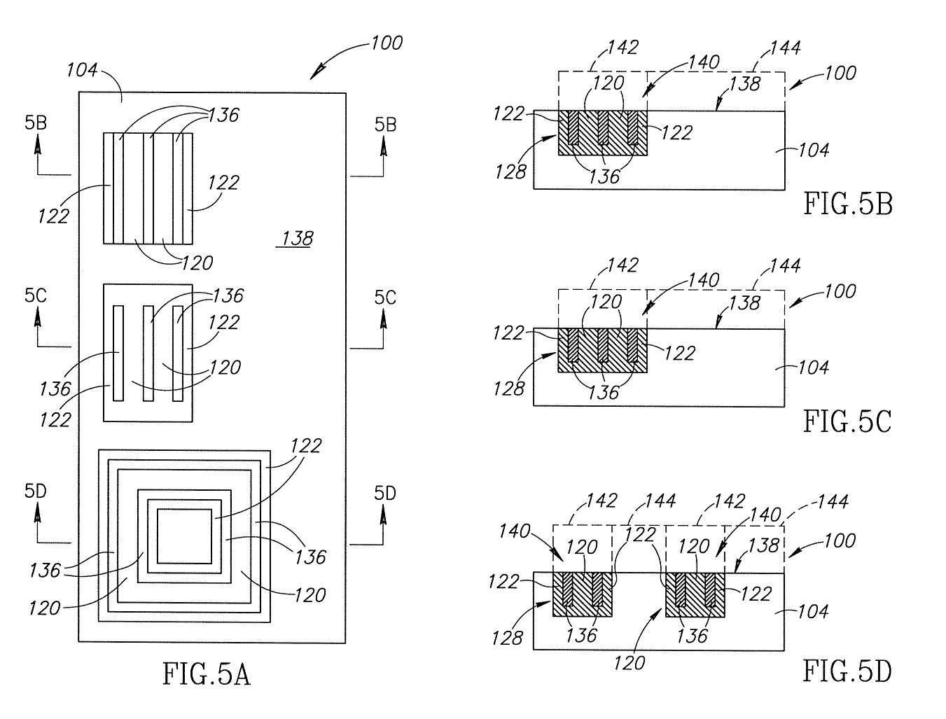

FIGS. 5A-5D show the wafer assembly 100 after a planing or planarization process in which portions of the dielectric layer material 123 and the deposited layer material 134 (FIGS. 4A-4D) are removed. In the illustrated embodiment, the removed portions of the dielectric layer material 123 and the deposited layer material 134 include only the portions located above a finish surface 138 of the wafer assembly 100.

The remaining portions of the dielectric material 120 and the deposited material 136, which are located within the substantially large trench 128, operate to form an isolation pad 140 for the wafer assembly 100. In one embodiment, the isolation pad 140 may be sized to receive a micro-electro mechanical system (MEMS) device 142, while another type of component such as an image sensor 144 (e.g., a complementary metal-oxide-semiconductor (CMOS) sensor or a charge-coupled device (CCD) sensor) is located on the finish surface 138 and adjacent to the MEMS device 142.

Advantageously, the substantially large trench 128 formed according to the above-described processes allows for larger isolation pads 140 to be more efficiently and more quickly produced into the wafer assembly 100. In turn, larger MEMS devices or other larger components, sensors, circuits, etc. that need to be mounted on an isolation pad 140 may now be placed on the wafer assembly 100.

While the preferred embodiment of the invention has been illustrated and described, as noted above, many changes can be made without departing from the spirit and scope of the invention. Accordingly, the scope of the invention is not limited by the disclosure of the preferred embodiment. Instead, the invention should be determined entirely by reference to the claims that follow.

The embodiments of the invention in which an exclusive property or privilege is claimed are defined as follows:

1. A method for producing an isolation region on a silicon wafer, the method comprising:
etching a plurality of trenches into the silicon wafer based on a predetermined pattern, each trench having a depth that extends through at least a partial thickness of the silicon wafer, wherein each trench is defined by an intermediate silicon wall spaced apart from another silicon wall by a width of the trench; and
oxidizing at least the etched portion of the silicon wafer such that the silicon wall is substantially converted to a silicon dioxide wall to form at least a portion of an isolation pad in the silicon wafer, wherein a region under the isolation pad includes at least a volume previously occupied by the trenches and the intermediate silicon wall.

2. The method of claim 1, further comprising arranging the desired pattern on the surface of the silicon wafer with a masking material placed on the surface.

3. The method of claim 1, wherein etching the plurality of trenches into the silicon wafer includes deep reactive ion etching the plurality of trenches.

4. The method of claim 1, wherein etching the plurality of trenches into the silicon wafer includes removing an amount of silicon from the wafer to form the plurality of trenches.

5. The method of claim 1, wherein oxidizing the silicon wall includes growing a layer of silicon dioxide on desired regions of the silicon wafer.

6. The method of claim 1, further comprising depositing a material onto the oxidized portion of the silicon wafer, wherein depositing the material includes filling a plurality of second trenches formed in the silicon dioxide, wherein adjacently located second trenches are separated by a silicon dioxide wall.

7. The method of claim 6, wherein depositing the material onto the oxidized portion of the silicon wafer includes depositing silicon dioxide.

8. The method of claim 6, wherein depositing the material onto the oxidized portion of the silicon wafer includes depositing a metallic material.

9. The method of claim 7, further comprising annealing the deposited silicon dioxide to remove at least some interstitial spaces.

10. The method of claim 6, further comprising annealing the silicon wafer after depositing the material to remove spaces between the oxidized portion and the deposited material.

11. The method of claim 1, further comprising finishing the silicon wafer to produce a substantially planar top surface.

12. The method of claim 11, wherein finishing the silicon wafer includes removing an amount of the deposited material and an amount of silicon dioxide to produce the substantially planar top surface.

13. A silicon wafer comprising:
a silicon substrate having a support surface located adjacent to a substrate trench formed in the silicon substrate, the substrate trench formed through an oxidation process wherein at least one silicon wall separating two previously etched trenches is converted to a silicon dioxide wall; and
an isolation material including at least the silicon dioxide wall received in the substrate trench and substantially filling the substrate trench, wherein an isolation surface formed by the isolation material is substantially flush and located adjacent to the support surface of the silicon substrate.

14. The silicon wafer of claim 13, further comprising an image sensor positioned on the support surface of the silicon substrate and a micro-electro mechanical system positioned on the isolation surface of the isolation material.

15. The silicon wafer of claim 14, wherein the image sensor includes a complementary metal-oxide-semiconductor (CMOS) sensor.

16. The silicon wafer of claim 13, wherein the isolation material includes an amount of silicon dioxide material grown in the substrate trench and an amount of oxide material deposited in the substrate trench.

17. The silicon wafer of claim 13, wherein the isolation material includes sidewalls made of silicon dioxide, wherein the silicon dioxide wall is located between the sidewalls.
